(19) United States
(12) Patent Application Publication
(10) Pub. No.: US 2016/0064399 A1
(43) Pub. Date: Mar. 3, 2016

(54) NONVOLATILE SEMICONDUCTOR MEMORY DEVICE AND METHOD OF MANUFACTURING THE SAME

(71) Applicant: Kabushiki Kaisha Toshiba, Minato-ku (JP)

(72) Inventors: Hiroaki NAITO, Yokkaichi (JP); Tatsuya FUKUMURA, Yokkaichi (JP)

(73) Assignee: Kabushiki Kaisha Toshiba, Minato-ku (JP)

(21) Appl. No.: 14/568,255

(22) Filed: Dec. 12, 2014

Related U.S. Application Data
(60) Provisional application No. 62/042,473, filed on Aug. 27, 2014.

(51) Int. Cl. H01L 27/115; H01L 29/66

(52) U.S. Cl. CPC H01L 27/11524; H01L 27/11546; H01L 27/11548; H01L 29/66825; H01L 29/66553

(57) ABSTRACT

According to one embodiment, a nonvolatile semiconductor memory device includes a memory cell region and a peripheral circuit region arranged on a semiconductor substrate. In the peripheral circuit region, a stacked body including a tunnel insulating film, a floating gate electrode film, an inter-electrode insulating film, and a control gate electrode film stacked in this order, a first insulating film and a second insulating film are stacked on the semiconductor substrate. The peripheral circuit region includes a contact region where the stacked body removed a film above the floating gate electrode film, the first insulating film and the second insulating film are stacked. The peripheral circuit region includes contact provided within a region where the contact region is formed, and one end of the contact is in the second insulating film, and the other end of the contact is in the floating gate electrode film.

### CROSS-REFERENCE TO RELATED APPLICATIONS

This application is based upon and claims the benefit of priority from U.S. Provisional Application No. 62/042,473, filed on Aug. 27, 2014; the entire contents of which are incorporated herein by reference.

### FIELD

Embodiments described herein relate generally to a nonvolatile semiconductor memory device and method of manufacturing the same.

### BACKGROUND

Along with higher integration of nonvolatile semiconductor memory devices, the half pitch of memory cells has been shrunk in a nanometer size. As this half pitch is reduced, the structure in the height direction is also downsized. Consequently, it has become more difficult to control penetration of contact patterns. Contact patterns arranged in a peripheral circuit region are formed such that their bottoms are present within a range of the thickness of floating gate electrodes. However, near the positions for forming the contact patterns in the peripheral circuit region, the film thickness of the floating gate electrode film is smaller than its film thickness in the memory cell region. This means that it is difficult to take a sufficient margin in forming the contact patterns. Consequently, the contact patterns cause positional variations of their bottoms, depending on the location. Due to these variations, some of the contact patterns come to penetrate the floating gate electrode film to a layer below, and so the resistance of the contact patterns is increased and the resistance of the contact patterns becomes uneven.

### BRIEF DESCRIPTION OF THE DRAWINGS

FIG. 1 is a sectional view schematically showing an example of a configuration of a nonvolatile semiconductor memory device according to an embodiment;

FIGS. 2A to 2H are sectional views schematically showing an example of a sequence of a method of manufacturing the nonvolatile semiconductor memory device according to the embodiment;

FIGS. 3A to 3D are sectional views schematically showing an example of a sequence of a method of manufacturing an ordinary nonvolatile semiconductor memory device; and

FIG. 4 is a sectional view schematically showing a state where a contact hole penetrates a floating gate electrode film in an ordinary nonvolatile semiconductor memory device.

### DETAILED DESCRIPTION

In general, according to one embodiment, a nonvolatile semiconductor memory device includes a memory cell region and a peripheral circuit region arranged on a semiconductor substrate. The memory cell region is equipped with a plurality of memory cell transistors. Each of the memory cell transistors comprises a stacked gate structure including a tunnel insulating film, a floating gate electrode film, an inter-electrode insulating film, and a control gate electrode film stacked in this order on the semiconductor substrate. The peripheral circuit region is equipped with a stacked body including the tunnel insulating film, the floating gate electrode film, the inter-electrode insulating film, and the control gate electrode film stacked in this order, a first insulating film and a second insulating film that are stacked on the semiconductor substrate. The peripheral circuit region includes a contact region where the stacked body removed a film above the floating gate electrode film, the first insulating film and the second insulating film are stacked. The peripheral circuit region includes a contact provided within a region where the contact region is formed. One end of the contact is in the second insulating film, and the other end of the contact is in the floating gate electrode film.

An exemplary embodiment of a nonvolatile semiconductor memory device and method of manufacturing the same will be explained below in detail with reference to the accompanying drawings. The present invention is not limited to the following embodiment. The sectional views of a nonvolatile semiconductor memory device used in the following embodiment are schematic, and so the relationship between the thickness and width of each layer and/or the thickness ratios between respective layers may be different from actual states.

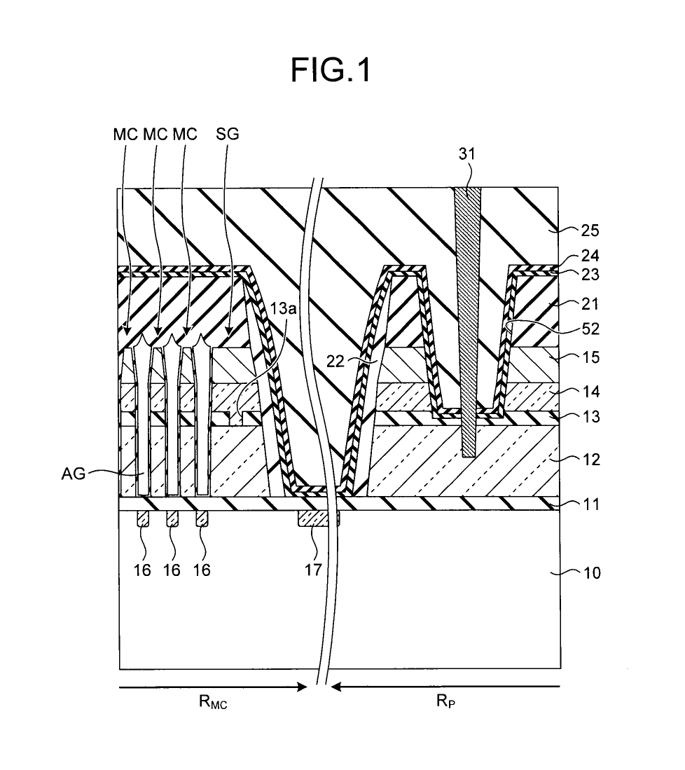

FIG. 1 is a sectional view schematically showing an example of a configuration of a nonvolatile semiconductor memory device according to an embodiment. FIG. 1 shows part of a memory cell region R_{MC} and a peripheral circuit region R_{P}, formed on a semiconductor substrate 10. In the memory cell region R_{MC}, there is arranged a memory unit that includes two selection transistors SG and a memory cell array including a plurality of memory cell transistors (which will be referred to as memory cells) MC connected in series. FIG. 1 shows only part of the memory unit (namely, one selection transistor SG and three memory cells MC). Further, although not shown in FIG. 1, the memory unit is arranged in a two dimensional state on the semiconductor substrate 10.

Each of the memory cells MC includes a stacked gate structure and impurity diffusion regions 16 on the semiconductor substrate 10. The stacked gate structure includes a tunnel insulating film 11, a floating gate electrode film 12, an inter-electrode insulating film 13, a control gate electrode film 14, and a metal electrode film 15 stacked in this order on the semiconductor substrate 10. The impurity diffusion regions 16 are formed near the surface of the semiconductor substrate 10 on the opposite sides in the gate length direction of the stacked gate structure, and they serve as source/drain regions. Each of the impurity diffusion regions 16 is shared by memory cells MC or a memory cell MC and a selection transistor SG, which are adjacent to each other in the gate length direction.

Each of the selection transistors SG includes a gate structure and impurity diffusion regions 16 and 17 on the semiconductor substrate 10. The gate structure includes the tunnel insulating film 11, the floating gate electrode film 12, the inter-electrode insulating film 13, the control gate electrode film 14, and the metal electrode film 15 stacked in this order on the semiconductor substrate 10. The inter-electrode insulating film 13 includes an opening 13a formed therein to penetrate it in the thickness direction. This opening 13a is filled with part of the control gate electrode film 14. Consequently, the floating gate electrode film 12 is electrically connected to the control gate electrode film 14. In other words, the gate electrode of each of the selection transistors SG is formed of the floating gate electrode film 12 and the control gate electrode film 14. The impurity diffusion regions 16 and 17 are formed near the surface of the semiconductor substrate 10 on the opposite sides in the gate length direction of the gate structure, and they serve as source/drain regions. The impurity diffusion region 16 is shared by this selection transistor SG and a memory cell MC adjacent thereto in the gate length direction. The impurity diffusion region 17 is formed on the side opposite to the memory cells MC.

The semiconductor substrate 10 may be formed of a silicon substrate doped with an N-type impurity or a P-type impurity. The tunnel insulating film 11 may be formed of a thermal oxide film, thermal oxynitride film, CVD (Chemical Vapor Deposition) oxide film, or CVD oxynitride film. The floating gate electrode film 12 may be formed of a polycrystalline silicon film doped with an N-type impurity or a P-type impurity; a metal film or poly-metal film using Mo, Ti, W, Al or Ta; or a nitride film. The inter-electrode insulating film 13 may be formed of a silicon oxide film; a silicon nitride film; an ONO (Oxide-Nitride-Oxide) film having a stacked structure of a silicon oxide film with a silicon nitride film; a high dielectric constant film, such as an aluminum oxide film or a hafnium oxide film; or a stacked structure of a high dielectric constant film with a low dielectric constant film, such as a silicon oxide film or silicon nitride film. The control gate electrode film 14 may be formed of a polycrystalline silicon film doped with an N-type impurity or a P-type impurity; or a stacked structure of a polycrystalline silicon film with a metal silicide film. The metal electrode film 15 may be formed of a metal film using Mo, Ti, W, Al, or Ta; or a poly-metal film.

An insulating film 21 is formed on the upper side of the memory unit, such that air gaps AG are formed in the memory unit, between the stacked gate structures adjacent to each other and between a stacked gate structure and a gate structure adjacent to each other. The insulating film 21 may be formed of a silicon oxide film formed by, e.g., a plasma CVD method. A spacer film 22 is formed on one side of a stacked body including the gate structure of each of the selection transistors SG and the insulating film 21.

In the peripheral circuit region R_{P}, there is arranged a circuit (not shown) for controlling operations of the memory cells MC and the selection transistors SG in the memory cell region R_{MC}. Further, contacts 31 are formed in the peripheral circuit region R_{P}. Each of the contacts 31 is connected to another circuit in the peripheral circuit region R_{P} via an upper wiring layer (not shown). The peripheral circuit region R_{P} has a layer structure similar to that of the memory cell region R_{MC}. In this example, the structure includes the tunnel insulating film 11, the floating gate electrode film 12, the inter-electrode insulating film 13, the control gate electrode film 14, the metal electrode film 15, and the insulating film 21 stacked on the semiconductor substrate 10.

In the peripheral circuit region R_{P}, contact openings 52 are formed such that they penetrate portions from the insulating film 21 to the lower surface of the control gate electrode 14. The contacts 31 are arranged within a range of the region for forming each of the contact openings 52, and they reach the floating gate electrode film 12.

In the memory cell region R_{MC} and the peripheral circuit region R_{P}, liner films 23 and 24 are formed to cover the stacked films, and an insulating film 25 is further formed above the liner films 23 and 24. The liner films 23 and 24 serve as a stopper in forming contact holes in which the contacts 31 are to be embedded. For example, each of the liner films 23 and 24 may be formed of a silicon nitride film or the like. The insulating film 25 is formed to cover the portions above the semiconductor substrate 10. The upper surface of the insulating film 25 is positioned higher than the upper surface of the insulating film 21 and is planarized.

In this embodiment, as described above, the contact openings 52 are formed in the peripheral circuit region R_{P}, such that they penetrate the insulating film 21, the metal electrode film 15, and the control gate electrode film 14 in the thickness direction. Accordingly, the lower ends of the contact openings 52 are present within a range of the thickness of the inter-electrode insulating film 13, and they do not reach the floating gate electrode film 12. In this way, since the positions of the contact openings 52 are set not to reach the floating gate electrode film 12, the lower ends of contact holes formed in the contact openings 52 can be more easily controlled to be within a range of the thickness of the floating gate electrode film 12.

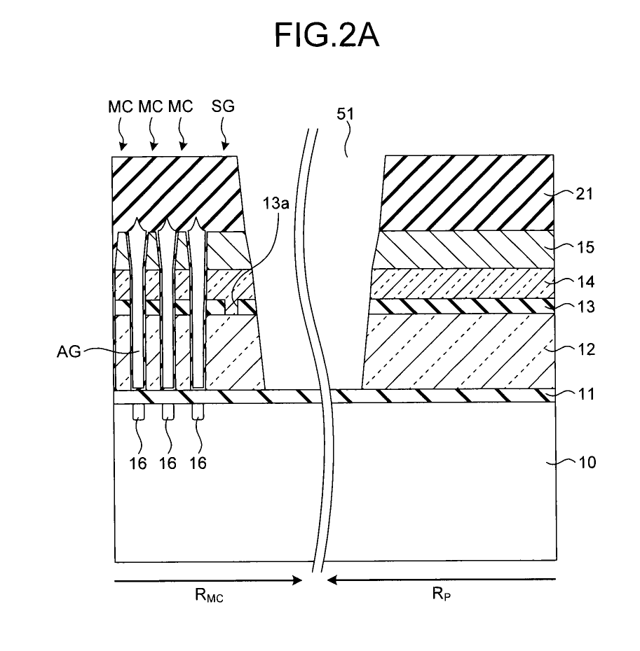

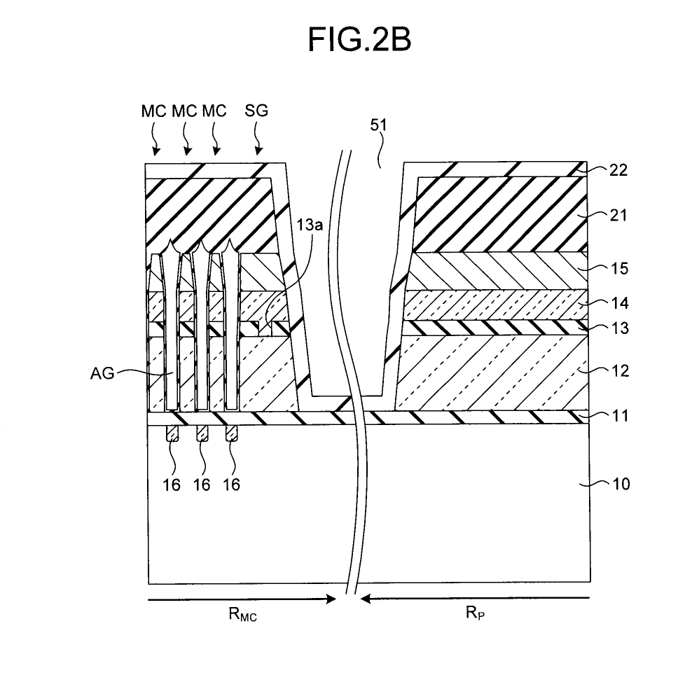

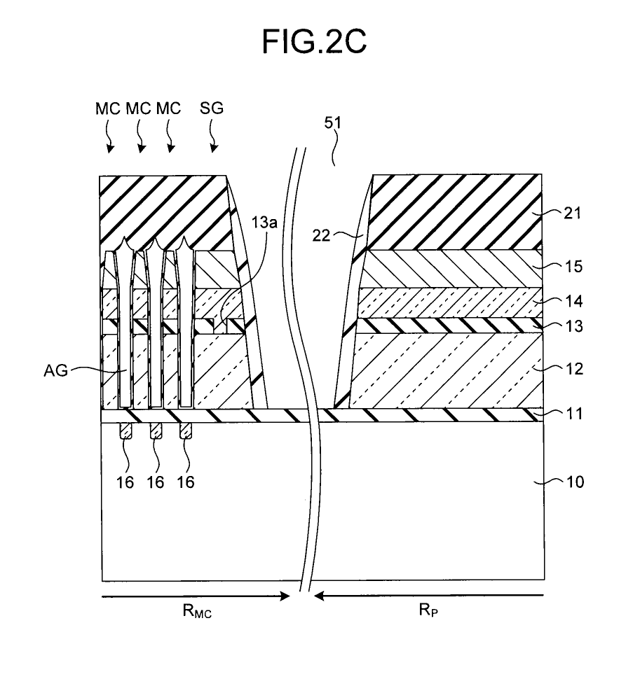

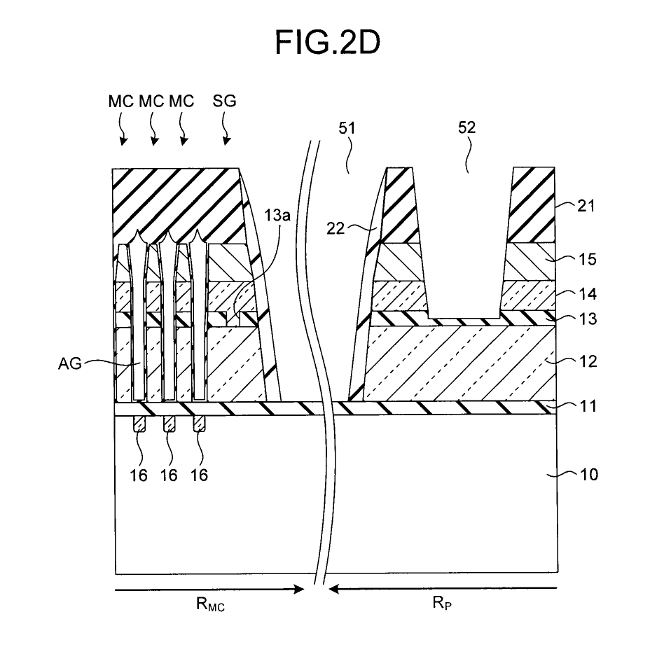

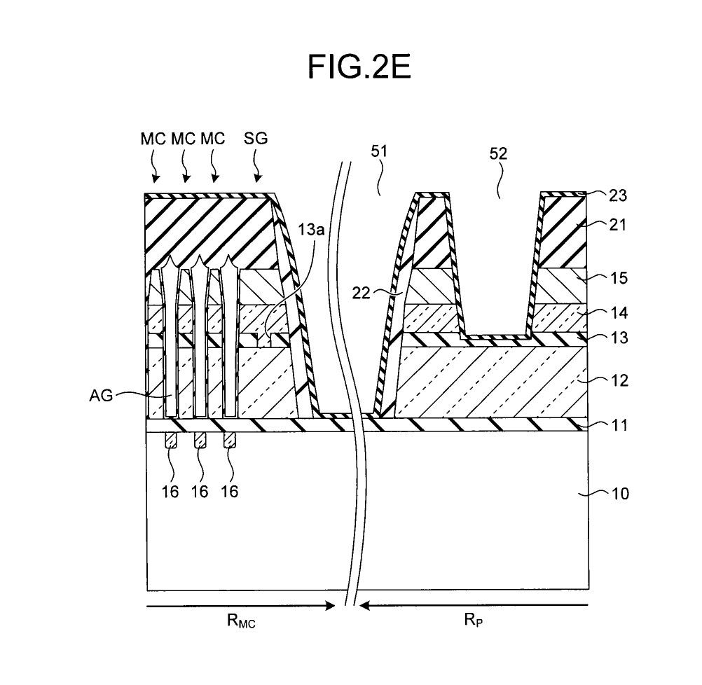

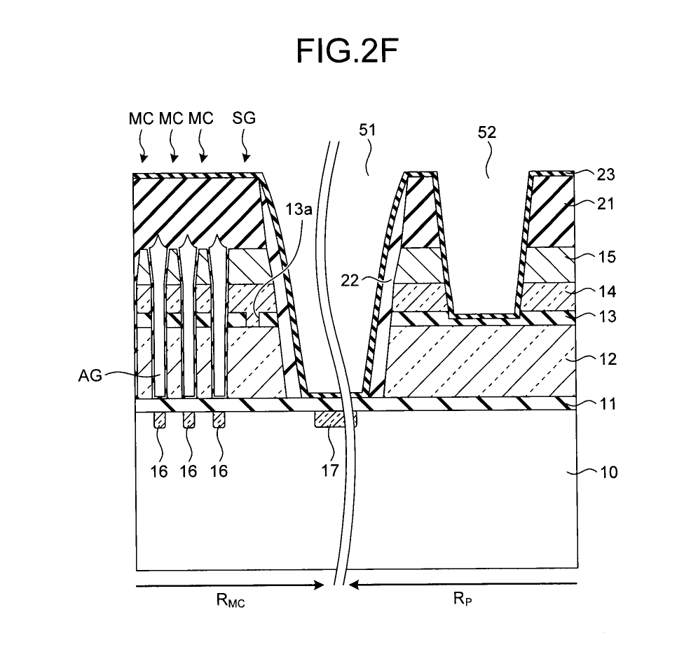

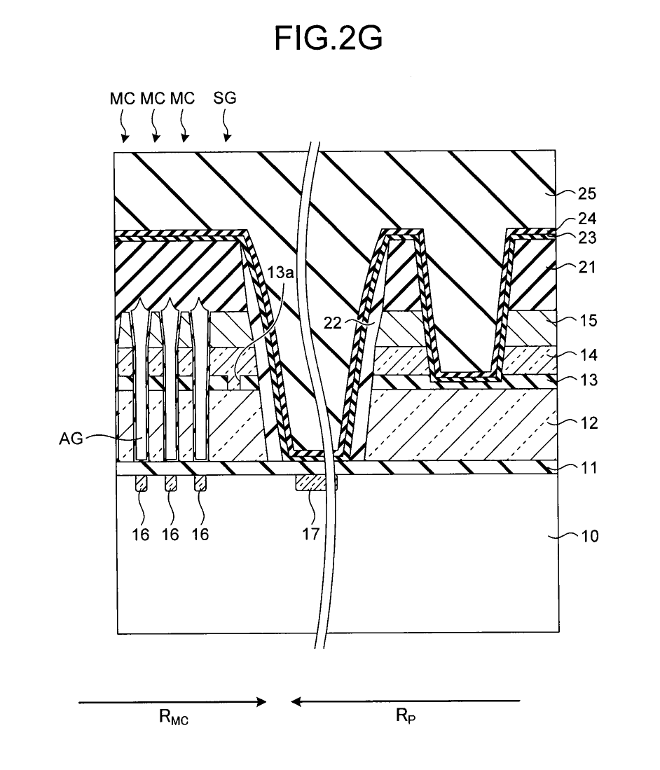

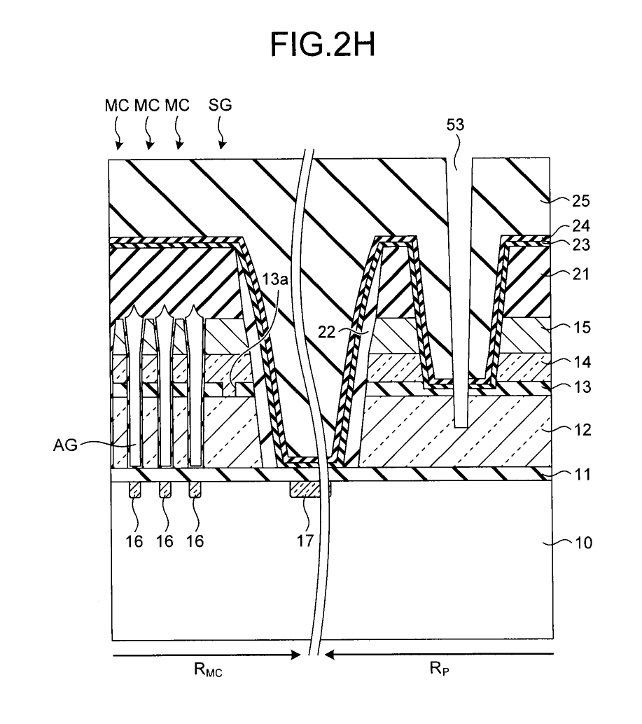

Next, an explanation will be given of a method of manufacturing the nonvolatile semiconductor memory device having configuration described above. FIGS. 2A to 2H are sectional views schematically showing an example of a sequence of a method of manufacturing the nonvolatile semiconductor memory device according to the embodiment.

At first, as shown in FIG. 2A, in accordance a sequence similar to an ordinary method of manufacturing a nonvolatile semiconductor memory device, the stacked gate structures of the memory cells MC and the gate structures of the selection transistors SG are formed in the memory cell region R_{MC}, and the insulating film 21 is further formed to cover their upper sides. More specifically, the tunnel insulating film 11, the floating gate electrode film 12, and the inter-electrode insulating film 13 are stacked on the semiconductor substrate 10. The opening 13a is formed in each of the positions for forming the selection transistors SG, such that it penetrates the inter-electrode insulating film 13 in the thickness direction. At this time, the film thickness of the tunnel insulating film 11 is 40 nm, for example. The film thickness of the floating gate electrode film 12 is 50 nm, for example. The film thickness of the inter-electrode insulating film 13 is 10 nm, for example.

Thereafter, the control gate electrode film 14 and the metal electrode film 15 are formed. The control gate electrode film 14 is formed to fill the opening 13a formed in the inter-electrode insulating film 13. The film thickness of the control gate electrode film 14 is 15 nm, for example. The film thickness of the metal electrode film 15 is 40 nm, for example. Then, portions from the metal electrode film 15 to the lower surface of the floating gate electrode film 12 in the memory cell region R_{MC} are etched into a predetermined shape to form the stacked gate structures. Thereafter, an impurity of a predetermined conductivity type is implanted into the regions of the upper surface of the semiconductor substrate 10 between the stacked gate structures by use of an ion implantation method, and is then activated to form the impurity diffusion regions 16. The impurity diffusion regions 16 provide the source/drain regions of the memory cells MC. Further, the impurity diffusion regions 16 provide one of the source/drain regions of each of the selection transistors SG.

Then, the insulating film 21 is formed on the metal electrode film 15 by, e.g., a plasma CVD method, such that it is not embedded in the air gaps AG between the stacked gate structures. The film thickness of the insulating film 21 is 200 nm, for example. Then, portions from the insulating film 21 to the lower surface of the floating gate electrode film 12 are etched to form trenches 51. The gate structures of the selection transistors SG are respectively formed by these trenches 51. At this time, in the peripheral circuit region R_{P}, the regions for forming contacts are in a state where portions from the tunnel insulating film 11 to the insulating film 21 are stacked.

Then, as shown in FIG. 2B, the spacer film 22 is formed all over on the semiconductor substrate 10. For example, the spacer film 22 is formed of a TEOS (Tetraethoxysilane) film having a thickness of 35 nm. The spacer film 22 is formed to cover the inner surface (side surface and bottom surface) of each of the trenches 51 in a conformal state.

Thereafter, as shown in FIG. 2C, the spacer film 22 is etched back by use of anisotropic etching, such as an RIE (Reactive Ion Etching) method. This etching back is performed, until the part of the spacer film 22 present on the tunnel insulating film 11 is removed. Consequently, the spacer film 22 becomes a sidewall film of the gate structure of each of the selection transistors SG.

Then, as shown in FIG. 2D, a mask film (not shown) is formed above the semiconductor substrate 10. The mask film has a pattern including openings at the positions for forming the contact openings 52 in the peripheral circuit region R_{P}. Then, while this mask film is used as a mask, portions from the insulating film 21 to the lower surface of the control gate electrode film 14 are etched by use of anisotropic etching, such as an RIE method. More specifically, at first, the insulating film 21 is etched under conditions for etching the insulating film 21 more preferentially than the metal electrode film 15. At this time, the metal electrode film 15 serves as a stopper, and so the etching becomes slower when the processing reaches the metal electrode film 15. Then, the metal electrode film 15 and the control gate electrode film 14 are etched under conditions for etching the metal electrode film 15 and the control gate electrode film 14 more preferentially than the inter-electrode insulating film 13. At this time, the inter-electrode insulating film 13 serves as a stopper, and so the etching becomes slower when the processing reaches the inter-electrode insulating film 13. Consequently, the contact openings 52 are formed.

Thereafter, as shown in FIG. 2E, the liner film 23 is formed above the semiconductor substrate 10. The liner film 23 is formed to cover each of the trenches 51 and the contact openings 52 in a conformal state. For example, the liner film 23 may be formed of a silicon nitride film having a thickness of 5 nm. This liner film 23 is used to form the impurity diffusion region 17 of each of the selection transistors SG, so that the impurity diffusion region 17 can be formed near the upper side of the semiconductor substrate 10 under each of the trenches 51.

Then, as shown in FIG. 2F, an impurity of a predetermined conductivity type is implanted into a portion near the upper side of the semiconductor substrate 10 under each of the trenches 51 by use of an ion implantation method, and is then activated to form the impurity diffusion region 17. This impurity diffusion region 17 serves as one of the source/drain regions of each of the selection transistors SG.

Thereafter, as shown in FIG. 2G, the liner film 24 is formed above the semiconductor substrate 10. The liner film 24 is formed to cover each of the trenches 51 and the contact openings 52 in a conformal state. The liner film 24 may be a film made of the same material as that of the liner film 23. For example, the liner film 24 may be formed of a silicon nitride film having a thickness of 25 nm. Since the thickness of the liner film 23 is insufficient to serve as a stopper in forming contact holes later, the liner film 24 is further formed. On the other hand, the total thickness of the liner films 23 and 24 is too large to implant an impurity by use of ion implantation, as shown in FIG. 2F, and so the impurity diffusion region 17 can be hardly formed. Consequently, the liner films 23 and 24 are separately formed in two steps.

Further, the insulating film 25 is formed on the liner film 24. The insulating film 25 is formed to fill each of the trenches 51 and the contact openings 52 and to be higher than the upper surface of the liner film 24 above the insulating film 21. The insulating film 25 is made of a material different from that of the liner film 24, and is formed of, e.g., a silicon oxide film. Thereafter, the upper surface of the insulating film 25 is planarized by polishing by use of a CMP (Chemical Mechanical Polishing) method.

Then, as shown in FIG. 2H, a mask film (not shown) is formed on the insulating film 25, and is subjected to patterning to have openings at the positions for forming contact holes 53. The positions for forming the contact holes 53 are present within the contact openings 52 in the peripheral circuit region R_{P}. Thereafter, the contact holes 53 are formed by etching by use of anisotropic etching, such as an RIE method, while the mask film is used as a mask. At this time, the etching is first performed under conditions for etching the insulating film 25 more preferentially than the liner films 24 and 23, so that the liner films 24 and 23 serve as a stopper. Then, the liner films 24 and 23 are etched, and then the floating gate electrode film 12 is etched. At this time, the etching time is controlled such that the floating gate electrode film 12 is partly left to have a predetermined thickness (for example, 10 nm) from the upper surface of the tunnel insulating film 11.

It should be noted that, when the contact holes 53 are formed, the etching can be once stopped at the liner films 24 and 23, and then the floating gate electrode film 12 is etched. Consequently, when the contact holes 53 are formed, the cut amounts of the floating gate electrode film 12 can be set at almost the same value among the contact holes 53 at respective positions.

Then, a conductive film is embedded in the contact holes 53 to form the contacts 31. For example, the contacts 31 may be made of tungsten. With the processes described above, the nonvolatile semiconductor memory device having the configuration shown in FIG. 1 is obtained.

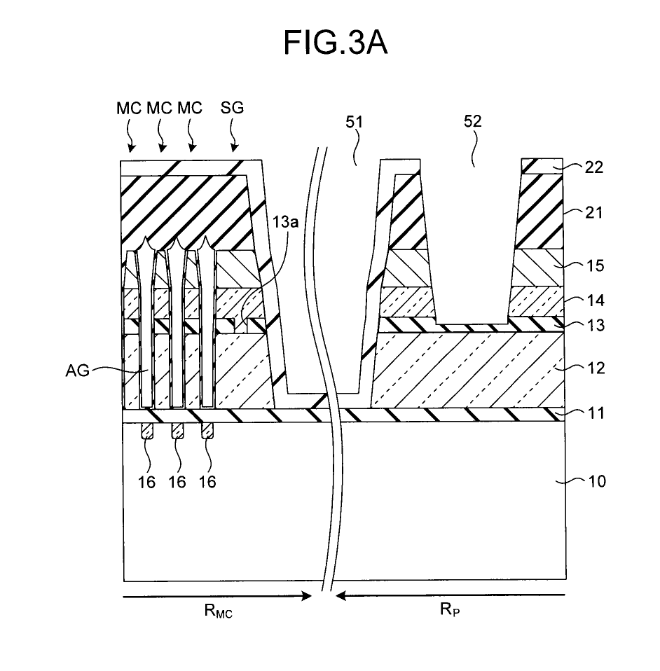

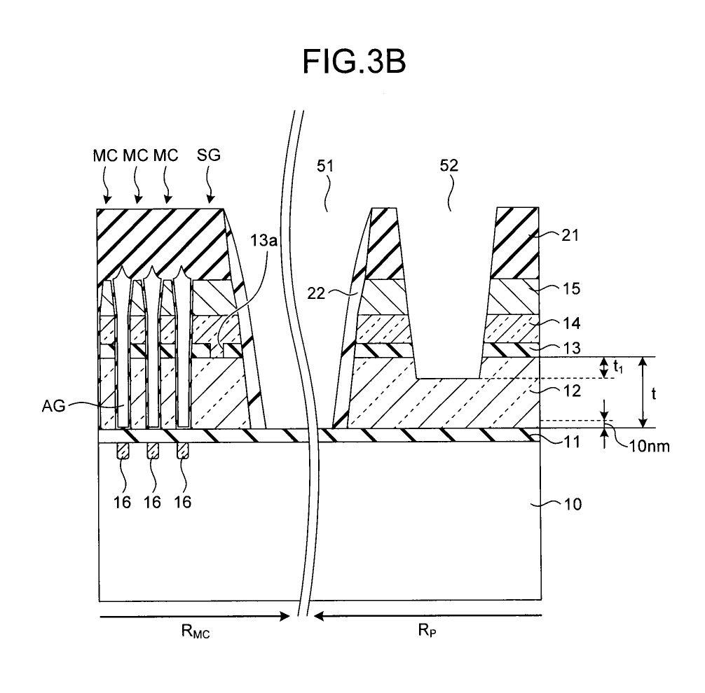

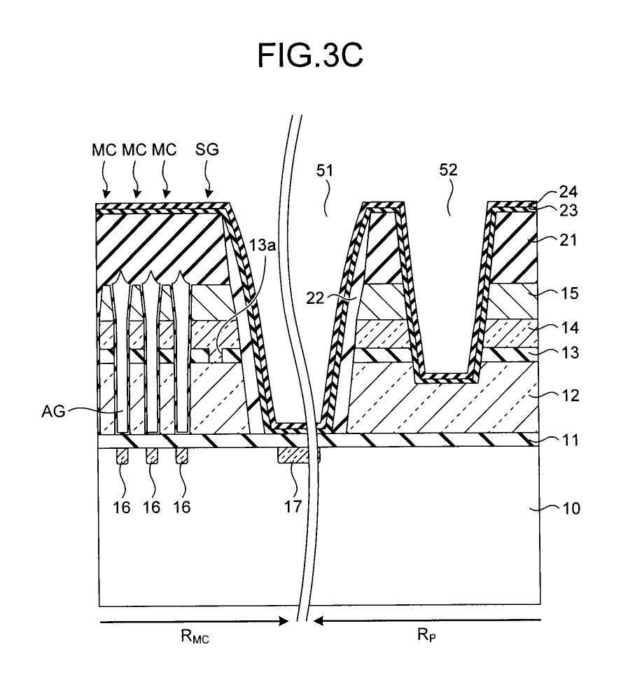

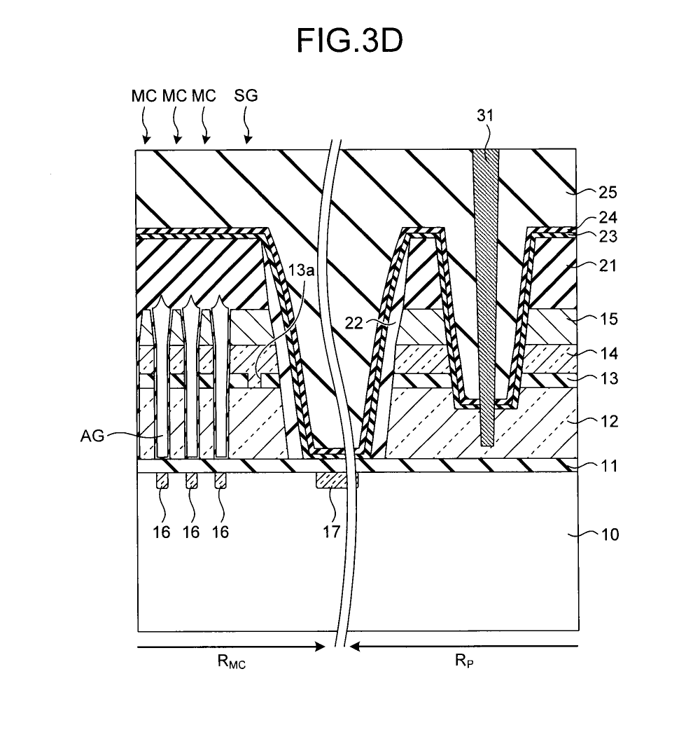

Next, in order to describe effects of this embodiment relative to an ordinary manufacturing method, an explanation will be given of a method of manufacturing an ordinary nonvolatile semiconductor memory device. FIGS. 3A to 3D are sectional views schematically showing an example of a sequence of a method of manufacturing an ordinary nonvolatile semiconductor memory device. This sequence is the same as the sequence according to the embodiment in the parts explained above with reference to FIGS. 2A and 2B, and so their descriptions will be omitted.

As shown in FIG. 3A, a mask film (not shown) is formed above the semiconductor substrate 10. The mask film has a pattern including openings at the positions for forming the contact openings 52 in the peripheral circuit region R_{P}. Then, while this mask film is used as a mask, portions from the insulating film 21 to the lower surface of the control gate electrode film 14 are etched by use of anisotropic etching, such as an RIE method. This etching process is almost the same as that explained with reference to FIG. 2D.

Then, as shown in FIG. 3B, the spacer film 22 is etched back by use of anisotropic etching, such as an RIE method. This etching back is performed, until the part of the spacer film 22 present on the tunnel insulating film 11 is removed. Consequently, the spacer film 22 becomes a sidewall film of the gate structure of each of the selection transistors SG. At this time, the contact openings 52 are further dug down. Consequently, the bottoms of the contact openings 52 reach the floating gate electrode film 12.

Thereafter, as shown in FIG. 3C, the liner film 23 is formed above the semiconductor substrate 10. Then, an impurity of a predetermined conductivity type is implanted into a portion near the upper side of the semiconductor substrate 10 under each of the trenches 51 by use of an ion implantation method, and is then activated to form the impurity diffusion region 17. Then, the liner film 24 is formed.

Then, as shown in FIG. 3D, the insulating film 25 is formed above the semiconductor substrate 10, and its upper surface is planarized. Further, contact holes are formed within the contact openings 52 in the peripheral circuit region R_{P}, and a conductive film is embedded in the contact holes to form the contacts 31.

As described above, according to the ordinary method, after the spacer film 22 is formed, the contact openings 52 are formed by etching, and then the spacer film 22 is subjected to the etching back process. Consequently, as shown in FIG. 3B, the positions of the contact openings 52 are further dug down from the state immediately after its formation shown in FIG. 3A. Thus, the bottom positions of the contact openings 52 reach the floating gate electrode film 12, as described above. It is assumed that the thickness of the floating gate electrode film 12 is denoted with “t” [nm], and the digging amount of each of the contact openings 52 in the floating gate electrode film 12 is denoted with “t₁” [nm]. In this case, if the margin of the contact hole formation is set at 10 nm from the lower surface of the floating gate electrode film 12, the contact hole formation needs to control the cut amount of the floating gate electrode film 12 obtained by the contact hole formation so that the cut amount is t−(t₁+10) [nm] or less.

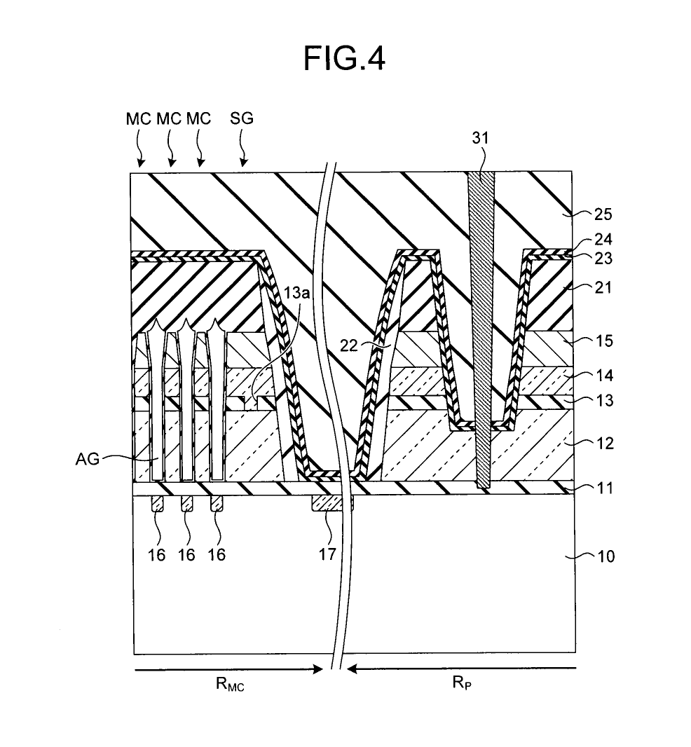

For example, in the case of “t”=50 nm and “t₁”=14 nm, it is necessary to control the cut amount of the floating gate electrode film 12 so that the cut amount is 26 nm or less. However, in practice, it is difficult to control the cut amount of the floating gate electrode film 12 so that the cut amount is 26 nm or less. Thus, there is a case where a contact hole penetrates the floating gate electrode film 12, depending on the location. FIG. 4 is a sectional view schematically showing a state where a contact hole penetrates a floating gate electrode film in an ordinary nonvolatile semiconductor memory device. As shown in FIG. 4, the contact hole penetrates the floating gate electrode film 12 and reaches the tunnel insulating film 11 formed below. If such a contact hole is present, the device cannot be used as a product. This is caused by the fact that the margin of the contact hole formation cannot be ensured because the contact openings 52 are dug down to the floating gate electrode film 12 in the etching back process of the spacer film 22, as shown in FIG. 3B.

On the other hand, according to this embodiment, after the spacer film 22 is formed, the spacer film 22 is etched back, and then the contact openings 52 are formed. Consequently, the contact openings 52 are not etched after the formation of the contact openings 52 shown in FIG. 2D until the formation of the contact holes 53 shown in FIG. 2H. In other words, the contact openings 52 have not changed their bottom surface positions since immediately after their formation. Thus, according to this embodiment, it suffices to control the cut amount of the floating gate electrode film 12 so that the cut amount is t−10 [nm] or less. In this case, there is given a room of “t₁” [nm] as compared with the ordinary case (in practice, it is “t₁” [nm] or more, because the inter-electrode insulating film 13 remains). Accordingly, this embodiment provides an effect of allowing a more room of the cut amount of the floating gate electrode film 12 in forming the contact holes 53.

For example, in the case of “t”=50 nm and “t₁”=14 nm, it suffices to control the cut amount of the floating gate electrode film 12 so that the cut amount is 40 nm or less. This is a sufficient room as compared with 26 nm or less obtained in the ordinary case, and so the penetration margin of the floating gate electrode film 12 can be increased when the contact holes 53 are formed.

Further, in this embodiment, the contact openings 52 are processed by etching while the inter-electrode insulating film 13 is used as a stopper. Further, when the contact holes 53 are formed, the floating gate electrode film 12 is etched to a predetermined depth from this portion. Consequently, the contact holes 53 are prevented from causing positional variations of their bottom. Further, when the contacts 31 are embedded in the contact holes 53, the film thicknesses of the parts of the floating gate electrode film 12 below the respective contacts 31 become more constant, and so there is also provided an effect of reducing the resistance variations.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile semiconductor memory device comprising a memory cell region and a peripheral circuit region arranged on a semiconductor substrate, wherein
the memory cell region is equipped with a plurality of memory cell transistors, each of the memory cell transistors comprising a stacked gate structure including a tunnel insulating film, a floating gate electrode film, an inter-electrode insulating film, and a control gate electrode film stacked in this order on the semiconductor substrate,
in the peripheral circuit region, a stacked body including the tunnel insulating film, the floating gate electrode film, the inter-electrode insulating film, and the control gate electrode film stacked in this order, a first insulating film and a second insulating film are stacked on the semiconductor substrate, and
the peripheral circuit region includes a contact region where the stacked body removed a film above the floating gate electrode film, the first insulating film and the second insulating film are stacked, and includes a contact provided within a region where the contact region is formed, one end of the contact being in the second insulating film, and the other end of the contact being in the floating gate electrode film.

2. The nonvolatile semiconductor memory device according to claim 1, wherein,
in the memory cell region, a third insulating film is formed on the control gate electrode film, such that air gaps are respectively formed between the stacked gate structures adjacent to each other in the gate length direction, and
in the peripheral circuit region, the third insulating film is formed between the control gate electrode film and the first insulating film.

3. The nonvolatile semiconductor memory device according to claim 1, further including a metal electrode film formed on the control gate electrode film.

4. The nonvolatile semiconductor memory device according to claim 2, wherein the memory cell region is further equipped with a selection transistor configured to select the plurality of memory cell transistors, the selection transistor comprising a gate structure including the tunnel insulating film, the floating gate electrode film, the inter-electrode insulating film, and the control gate electrode film stacked in this order on the semiconductor substrate, and impurity diffusion regions formed in an upper surface of the semiconductor substrate on opposite sides of the gate structure in a gate length direction, the selection transistor being arranged on a side opposite to a row of the memory cell transistors arrayed in the gate length direction, and a spacer film being formed on one side surface of a stacked structure that is formed of the gate structure of the selection transistor and the third insulating film.

5. A method of manufacturing a nonvolatile semiconductor memory device comprising:
forming a stacked body including a tunnel insulating film, a floating gate electrode film, an inter-electrode insulating film, and a control gate electrode film on a semiconductor substrate;
forming memory cell transistors, each of which uses the stacked body as a stacked gate structure, in a memory cell region;
forming a first insulating film above the semiconductor substrate;
etching portions from the first insulating film to the floating gate electrode film to form trenches, such that a gate structure of a selection transistor is formed on each of opposite sides of a row of the memory cell transistors arrayed in a gate length direction;
forming a spacer film to cover an inner surface of the trenches;
etching back the spacer film to remove part of the spacer film at a bottom of each of the trenches;
removing a portion from the first insulating film to a lower surface of the control gate electrode film to form a contact opening, in a peripheral circuit region;
forming a first liner film to cover an inner surface of the contact opening;
forming a second insulating film on the semiconductor substrate to fill the contact opening and the trenches;
forming contact holes from the second insulating film to the floating gate electrode film at a position where the contact opening is formed, in the peripheral circuit region; and
forming a contact by embedding a conductive film in the contact holes.

6. The method of manufacturing a nonvolatile semiconductor memory device according to claim 5, wherein the forming of the contact holes includes etching the second insulating film by use of the first liner film as a stopper, then etching the floating gate electrode film to a predetermined depth in the floating gate electrode film.

7. The method of manufacturing a nonvolatile semiconductor memory device according to claim 5 further comprising:
forming a impurity diffusion region near an upper surface of the semiconductor substrate below each of the trenches, after the forming of the first liner film; and
forming a second liner film on the first liner film to cover an inner surface of the contact opening.

8. The method of manufacturing a nonvolatile semiconductor memory device according to claim 7, wherein the second liner film and the first liner film consist essentially of the same material.

9. The method of manufacturing a nonvolatile semiconductor memory device according to claim 5, wherein the forming of the stacked body includes further forming a metal electrode film on the control gate electrode film.

10. The method of manufacturing a nonvolatile semiconductor memory device according to claim 5, wherein the forming of the first insulating film includes forming the first insulating film on the memory cell transistors such that air gaps are respectively formed between the stacked gate structures adjacent to each other in the gate length direction.
